(19) United States
(12) Patent Application Publication
(10) Pub. No.: US 2023/0290680 A1
(43) Pub. Date: Sep. 14, 2023

(54) SELF-LIMITING GROWTH

(71) Applicant: Lam Research Corporation, Fremont, CA (US)

(72) Inventors: Joshua Collins, Sunnyvale, CA (US); Griffin John Kennedy, Livermore, CA (US); Hanna Bamnolker, Cupertino, CA (US); Michal Danek, Cupertino, CA (US); Shruti Vivek Thombare, Sunnyvale, CA (US); Patrick A. van Cleemput, Duvall, WA (US); Gorun Butail, Fremont, CA (US)

(21) Appl. No.: 18/310,523

(22) Filed: May 1, 2023

Related U.S. Application Data
(63) Continuation of application No. 16/764,812, filed on May 15, 2020.
(60) Provisional application No. 62/588,869, filed on Nov. 20, 2017.

(51) Int. Cl. H01L 21/768; H01L 21/285

(52) U.S. Cl. CPC H01L 21/76876; H01L 21/28568

(57) ABSTRACT

Provided herein are methods and apparatuses for forming metal films such as tungsten (W) and molybdenum (Mo) films on semiconductor substrates. The methods involve forming a reducing agent layer, then exposing the reducing agent layer to a metal precursor to convert the reducing agent layer to a layer of the metal. In some embodiments, the reducing agent layer is a silicon- (Si-) and boron- (B-) containing layer. The methods may involve forming the reducing agent layer at a first substrate temperature, raising the substrate temperature to a second substrate temperature, and then exposing the reducing agent layer to 10 the metal precursor at the second substrate temperature. The methods may be used to form fluorine-free tungsten or molybdenum films in certain embodiments. Apparatuses to perform the methods are also provided.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

Deposition of conductive materials such as tungsten films is an integral part of many semiconductor fabrication processes. These materials may be used for horizontal interconnects, vias between adjacent metal layers, contacts between metal layers and devices on the silicon substrate, and high aspect ratio features. As devices shrink and more complex patterning schemes are utilized in the industry, deposition of thin tungsten films becomes a challenge. These challenges include fluorine migration, which can cause device failure, as well as difficulty in depositing low resistivity films having good step coverage.

The background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Provided herein are methods and apparatuses for forming metal films such as tungsten (W) and molybdenum (Mo) films on semiconductor substrates. The methods involve forming a reducing agent layer, then exposing the reducing agent layer to a metal precursor to convert the reducing agent layer to a layer of the metal. In some embodiments, the reducing agent layer is a silicon- (Si-) and boron- (B-) containing layer. The methods may involve forming the reducing agent layer at a first substrate temperature, raising the substrate temperature to a second substrate temperature, and then exposing the reducing agent layer to the metal precursor at the second substrate temperature. The methods may be used to form fluorine-free tungsten or molybdenum films in certain embodiments. Apparatuses to perform the methods are also provided.

One aspect of the disclosure may be implemented in a method including providing a substrate including a structure; exposing the substrate to a reducing agent gas at a first substrate temperature of no more than 400° C. to form a conformal reducing agent layer on the structure; raising the temperature of the substrate to a second substrate temperature of at least 500° C.; and at the second substrate temperature, exposing the conformal reducing agent layer to a metal precursor to convert the conformal reducing agent layer to the metal.

In some embodiments, the first substrate temperature is no more than 350° C. In some embodiments, the first substrate temperature is no more than 300° C. In some embodiments, the reducing agent gas is a silicon-containing gas. In some embodiments, the reducing agent gas is a boron-containing gas. In some embodiments, the reducing agent gas is a mixture of a silicon-containing gas and a boron-containing gas. In some such embodiments, the reducing agent gas is a mixture of silane (SiH₄) and diborane (B₂H₆). In some embodiments, exposing the conformal reducing agent layer to a metal precursor comprises exposing the conformal reducing agent layer to hydrogen (H₂) gas. In some embodiments, the metal precursor is provided with H₂.

In some embodiments, exposing the conformal reducing agent layer to a metal precursor to convert the reducing agent layer to metal includes exposing the conformal reducing agent layer to alternating pulses of H₂ and the metal precursor. In some embodiments, the metal precursor is a tungsten chloride compound and the metal is tungsten. In some embodiments, the metal precursor is a molybdenum-containing compound and the metal is molybdenum. In some embodiments, the conformal reducing agent layer is formed directly on an oxide surface. In some embodiments, the conformal reducing agent layer is formed directly on a nitride surface. In some embodiments, the conformal reducing agent layer is between about 10 and 50 Angstroms thick. In some embodiments, the concentration of boron in the reducing agent layer decreases with increasing thickness. In some embodiments, the silicon:boron ratio in the mixture is at least 10:1.

Another aspect of the disclosure may be implemented in a method including providing a substrate including a structure; exposing the substrate to a mixture of a silicon- containing gas and a boron-containing gas at a first substrate temperature of no more than 400° C. to form a conformal reducing agent layer on the structure; raising the temperature of the substrate to a second substrate temperature of at least 500° C.; and at the second substrate temperature, exposing the conformal reducing agent layer to a tungsten-containing or molybdenum-containing precursor to convert the reducing agent layer to tungsten or molybdenum. In some embodiments, the silicon:boron ratio in the mixture is at least 10:1.

Another aspect of the disclosure may be implemented in a method including providing a substrate including a structure; exposing the substrate to a mixture of a silicon- containing gas and a boron-containing gas to form a conformal reducing agent layer on the structure; and exposing the conformal reducing agent layer to a molybdenum-containing precursor to convert the reducing agent layer to molybdenum.

Another aspect of the disclosure may be implemented in an apparatus including one or more chambers each configured to house a substrate; a support substrate in each of the one or more chambers; gas inlets configured to direct gas into each of the one or more chambers; a heater configured to heat the substrate support in each chamber; and a controller comprising program instructions for: heating the substrate support in one of the one more chambers to a first temperature of no more than 400° C. and directing a mixture of a silicon-containing gas and a boron-containing gas into said chamber; heating the substrate support in one of the one more chambers to a first temperature of at least 500° C. and, after the mixture is directed, directing a tungsten-containing or molybdenum-containing precursor into said chamber.

These and other aspects of the disclosure are discussed further below with reference to the drawings.

### BRIEF DESCRIPTION OF DRAWINGS

FIG. 1A shows an example metal stack that includes tungsten.

FIGS. 1B-1I are schematic examples of various structures in which tungsten or molybdenum may be deposited in accordance with disclosed embodiments.

FIG. 1J shows an example metal stack that includes molybdenum.

FIGS. 2A-2C provide process flow diagrams for methods performed in accordance with disclosed embodiments. In particular, FIG. 2A provides a process flow diagram for a method of depositing an elemental metal layer in a feature. FIGS. 2B and 2C provide examples of the method of FIG. 2A to deposit elemental tungsten and molybdenum, respectively

FIG. 3A shows tungsten conversion for various reducing agent gas mixtures and tungsten chloride exposures at 300° C. substrate temperature during conversion.

FIG. 3B shows molybdenum growth obtained using a silicon-boron reducing agent layer on both a thermal oxide (lower line) and TiN (upper line) substrate. FIG. 3C shows resistivity of the films.

FIG. 3D shows molybdenum growth for silicon-boron reducing agent layers of 10A, 20A, 30A, and 50A. FIG. 3E shows resistivity of the molybdenum layers as a function of reducing agent layer thickness.

FIG. 4 is a diagram of a processing system suitable for conducting deposition processes in accordance with disclosed embodiments.

FIG. 5 is a schematic illustration of a deposition chamber for conducting deposition processes in accordance with disclosed embodiments.

### DETAILED DESCRIPTION

Provided herein are methods and apparatuses for forming metal films such as tungsten (W) and molybdenum (Mo) films on semiconductor substrates. The methods involve forming a reducing agent layer, then exposing the reducing agent layer to a metal precursor to convert the reducing agent layer to a layer of the metal. In some embodiments, the reducing agent layer is a silicon- (Si-) and boron- (B-) containing layer. The methods may involve forming the reducing agent layer at a first substrate temperature, raising the substrate temperature to a second substrate temperature, and then exposing the reducing agent layer to the metal precursor at the second temperature. The methods may be used to form fluorine-free tungsten or molybdenum films in certain embodiments. Apparatuses to perform the methods are also provided.

Forming electrical contacts or lines in semiconductor device fabrication can involve filling features with tungsten or other electrically conductive materials. A nucleation tungsten layer can first be deposited into a via or contact. In general, a nucleation layer is a thin conformal layer that serves to facilitate the subsequent formation of a bulk material thereon. The tungsten nucleation layer may be deposited to conformally coat the sidewalls and bottom of the feature. Conforming to the underlying feature bottom and sidewalls can be critical to support high quality deposition. After the tungsten nucleation layer is deposited, bulk tungsten may be deposited by a CVD process by reducing tungsten hexafluoride (WF₆) or other tungsten-containing precursor using a reducing agent such as hydrogen (H₂). Bulk tungsten is different from a tungsten nucleation layer. Bulk tungsten as used herein refers to tungsten used to fill most or all of a feature, such as at least about 50% of the feature. Unlike a nucleation layer, which is a thin conformal film that serves to facilitate the subsequent formation of a bulk material thereon, bulk tungsten is used to carry current. Bulk tungsten is tungsten deposited to a thickness of at least 50 Å.

Distribution of a material within a feature may be characterized by its step coverage. For the purposes of this description, “step coverage” is defined as a ratio of two thicknesses, i.e., the thickness of the material inside the feature divided by the thickness of the material near the opening. For purposes of this document, the term “inside the feature” represents a middle portion of the feature located about the middle point of the feature along the feature's axis, e.g., an area between about 25% and 75% of the distance or, in certain embodiments, between about 40% and 60% of the distance along the feature's depth measured from the feature's opening, or an end portion of the feature located between about 75% and 95% of the distance along the feature's axis as measured from the opening. The term “near the opening of the feature” or “near the feature's opening” represents a top portion of the feature located within 25% or, more specifically, within 10% of the opening's edge or other element representative of the opening's edge. Step coverage of over 100% can be achieved, for example, by filling a feature wider in the middle or near the bottom of the feature than at the feature opening.

There are various challenges in tungsten fill as devices scale to smaller technology nodes and more complex patterning structures are used. Deposition of tungsten can involve the use of the fluorine-containing precursor tungsten hexafluoride (WF₆). However, the use of WF₆ results in some incorporation of fluorine into the deposited tungsten film. The presence of fluorine can cause electromigration and/or fluorine diffusion into adjacent components and damages contacts, thereby reducing the performance of the device. One challenge is reducing the fluorine concentration or content in the deposited tungsten film. As compared to larger features, a smaller feature having the same fluorine concentration in the tungsten film as a larger feature affects the performance of the device more substantially. For example, the smaller the feature, the thinner the films are deposited. As a result, fluorine in the deposited tungsten film is more likely to diffuse through the thinner films, thereby potentially causing device failure.

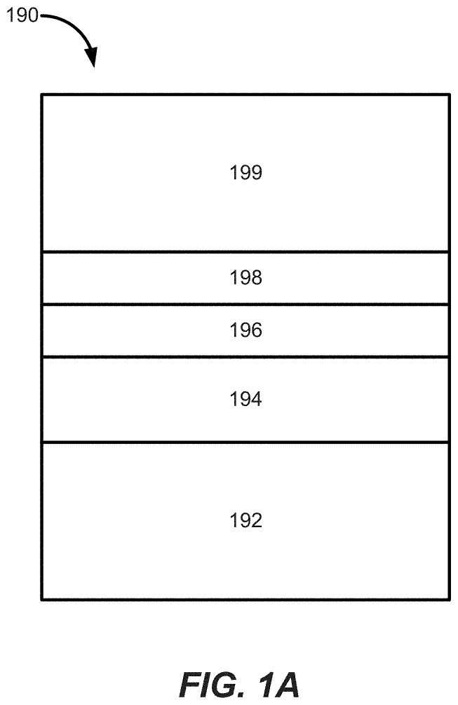

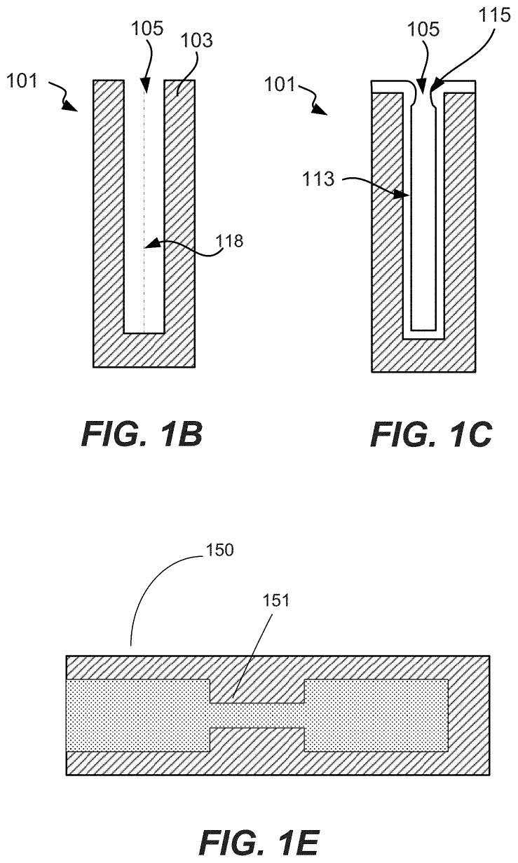

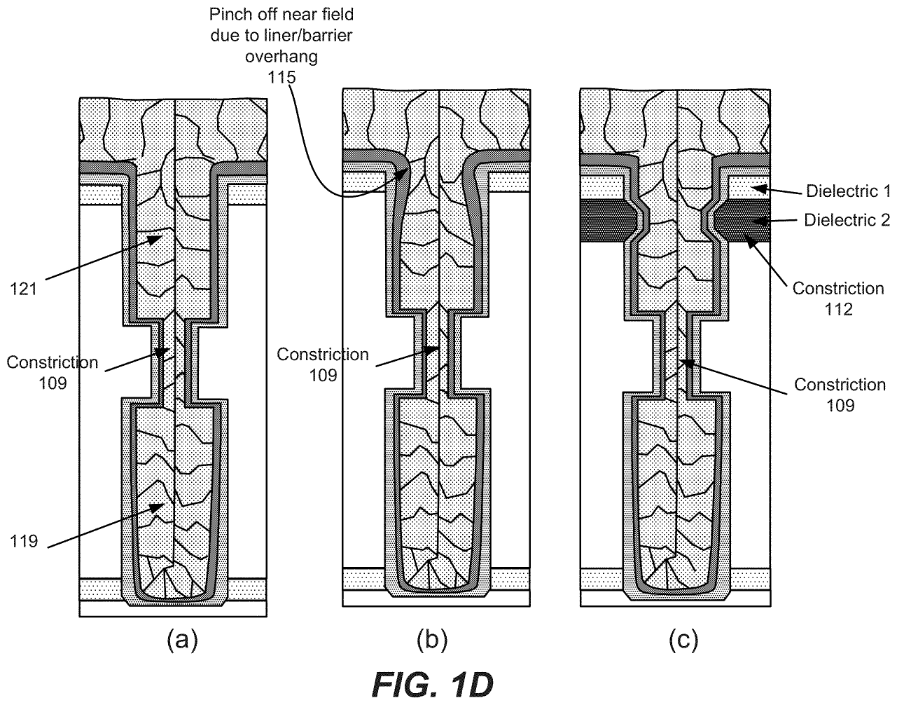

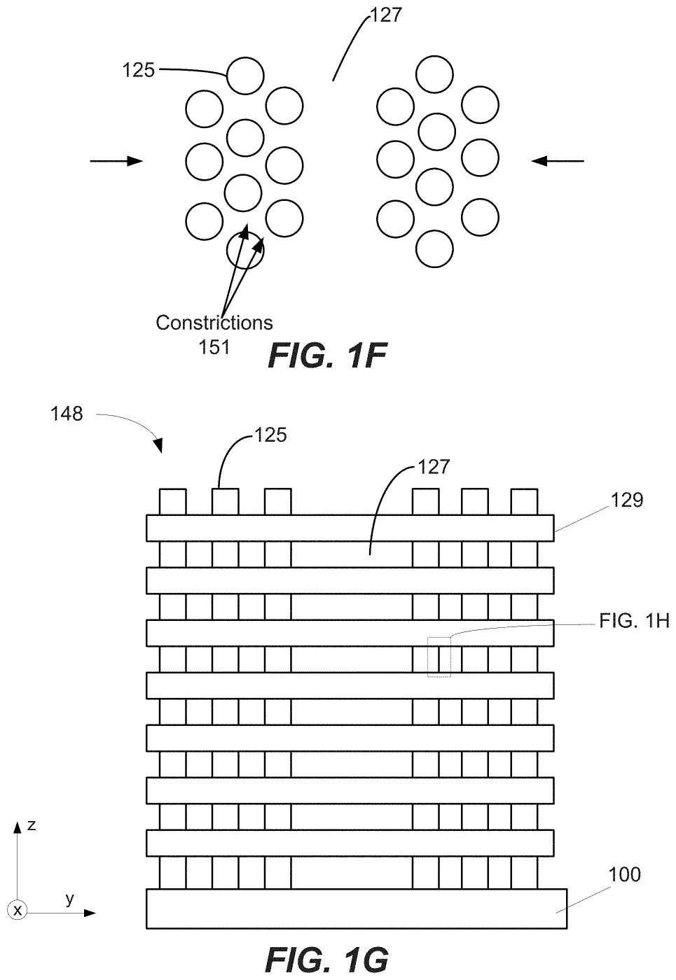

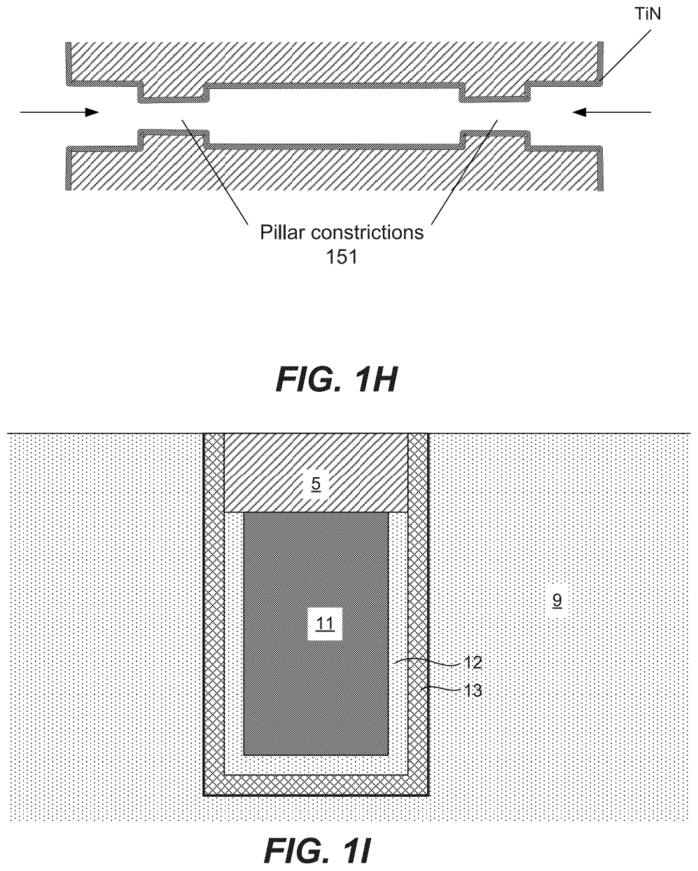

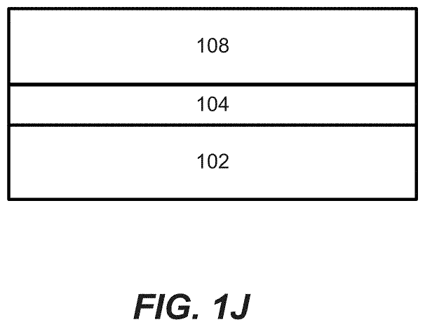

One method of preventing fluorine diffusion includes depositing one or more barrier layers prior to depositing tungsten to prevent fluorine from diffusing from tungsten to other layers of the substrate such as an oxide layer. For example, FIG. 1A shows an example stack of layers deposited on a substrate. Substrate 190 includes a silicon layer 192, an oxide layer 194 (e.g., titanium oxide (TiOx), tetraethyl orthosilicate (TEOS) oxide, etc.), a barrier layer 196 (e.g., titanium nitride (TiN)), a tungsten nucleation layer 198, and a bulk tungsten layer 199. Barrier layer 196 is deposited to prevent fluorine diffusion from the bulk tungsten layer 199 and the tungsten nucleation layer 198 to the oxide layer. However, as devices shrink, barrier layers become thinner, and fluorine may still diffuse from the deposited tungsten layers. Although chemical vapor deposition of bulk tungsten performed at a higher temperature results in lower fluorine content, such films have poor step coverage.

Another challenge is reducing resistance in the deposited tungsten films. Thinner films tend to have higher resistance than thicker films. As features become smaller, the tungsten contact or line resistance increases due to scattering effects in the thinner tungsten films. Low resistivity tungsten films minimize power losses and overheating in integrated circuit designs. Tungsten nucleation layers typically have higher electrical resistivities than the overlying bulk layers. Barrier layers deposited in contacts, vias, and other features, may also have high resistivities. Further, thin barrier and tungsten nucleation films occupy a larger percentage of smaller features, increasing the overall resistance in the feature. Resistivity of a tungsten film depends on the thickness of the film deposited, such that resistivity increases as thickness decreases due to boundary effects.

Another challenge is reducing stress on deposited films. Thinner tungsten films tend to have increased tensile stress. Depositing bulk tungsten films by chemical vapor deposition can result in a tensile stress greater than 2.5 GPa for a 200 Å film. High thermal tensile stress causes the substrate to curl, which makes subsequent processing difficult. For example, subsequent processes may include chemical mechanical planarization, deposition of materials, and/or clamping of the substrate to a substrate holder to perform processes in a chamber. However, these processes often rely on the substrate being flat, and a curled substrate results in nonuniform processing or inability to process the substrate. Although there are existing methods for reducing stress in films of other materials such as annealing, tungsten does not have the surface mobility to allow grains to be moved or altered once it is deposited due to its high melting point.

Fluorine-free tungsten (FFW) precursors are useful to prevent such reliability and integration issues or device performance issues. FFW precursors include metal organic precursors, but undesirable traces of elements from the metal organic precursors may be incorporated in the tungsten film as well, such as carbon, hydrogen, nitrogen, and oxygen. Some metal organic fluorine-free precursors are also not easily implemented or integrated in tungsten deposition processes.

One aspect of the disclosure relates to methods of depositing fluorine-free tungsten films having using a chlorine-containing tungsten precursor, or tungsten chloride (WClₓ). Tungsten chloride includes tungsten pentachloride (WCl₅), tungsten hexachloride (WCl₆), tungsten tetrachloride (WCl₄), tungsten dichloride (WCl₂), tungsten oxychlorides (WOₓCl_{y}) and mixtures thereof. Although examples herein refer to WCl₅ and WCl₆ as examples, it is understood that other tungsten chlorides may be used with disclosed embodiments. Films deposited using certain disclosed embodiments are fluorine-free.

In certain embodiments, the methods involve depositing a conformal reducing agent layer on a substrate. The substrate generally includes a feature to be filled with tungsten as described above, with the reducing agent layer is conformal to the topography of the substrate including the feature. The reducing agent layer is then exposed to a WClₓ precursor, which is reduced by the reducing agent layer. The conformal reducing agent layer is converted to a conformal tungsten layer. According to various embodiments, the WClₓ precursor may or may not be provided in the presence of hydrogen (H₂) gas.

In some embodiments, the conformal reducing agent layer is the only available reducing agent for WClₓ, excess WClₓ may be used to ensure complete conversion to tungsten (W). The conversion is self-limiting, with its step coverage defined by the step coverage of the reducing agent layer.

In some embodiments, the reducing agent layer and the subsequent tungsten layer is formed directly on an oxide surface, such as a silicon oxide (e.g., SiO₂) or aluminum oxide (e.g., Al₂O₃) surface. This eliminates the need for an adhesion/barrier layer such as a titanium nitride (TiN) layer or titanium/titanium nitride (Ti/TiN) bilayer. Formation of the tungsten layer directly on an oxide is possible because the oxide is not damaged exposure to WClₓ or chlorine gas byproduct. By eliminating TiN and other barrier layers, line resistance is reduced.

In some embodiments, the reducing agent layer formation and subsequent conversion to tungsten is performed without a tungsten nucleation layer. This also may reduce resistance.

In some embodiments, formation of the reducing agent layer and subsequent tungsten conversion are performed at different temperatures. By de-coupling the temperatures for reducing agent layer deposition and W conversion from WClₓ, excellent step coverage can be achieved during reducing agent layer deposition. The W conversion is self-limiting, preserving the step coverage.

In some embodiments, a dense, conformal, and fluorine-free tungsten layer eliminations fluorine damage associated with WF₆-based tungsten nucleation and bulk deposition. Further, in some embodiments, a high conversion temperature may be employed to increase the density of the tungsten layer, which can help reduce fluorine diffusion if a fluorine-containing precursor is used in subsequent tungsten deposition operations.

The methods described herein may also be used for deposition of molybdenum (Mo). Molybdenum may be used to form low resistance metallization stack structures and may take the place of tungsten in the structures described above. FIG. 1J shows another example of a material stack. In this example, the stack includes a substrate 102, a dielectric layer 104, with a Mo layer 108 deposited on the dielectric layer 104, without an intervening diffusion barrier layer. In alternate embodiments, the Mo layer 108 may be deposited on a TiN or other diffusion barrier layer. The Mo layer 108 may or may not include a Mo nucleation layer and a bulk Mo layer, and, in some embodiments, the Mo layer 108 may be deposited on a tungsten (W) or W-containing growth initiation layer. By using Mo, which has a lower electron mean free path than W, as the main conductor, lower resistivity thin films can be obtained.

Methods described herein are performed on a substrate that may be housed in a chamber. The substrate may be a silicon wafer, e.g., a 200-mm wafer, a 300-mm wafer, or a 450-mm wafer, including wafers having one or more layers of material, such as dielectric, conducting, or semi-conducting material deposited thereon. Substrates may have features such as via or contact holes, which may be characterized by one or more of narrow and/or re-entrant openings, constrictions within the feature, and high aspect ratios. A feature may be formed in one or more of the above described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIGS. 1B-1I are schematic examples of various structures in which tungsten may be deposited in accordance with disclosed embodiments. As described further below, molybdenum may be deposited in these structures as an alternative to or in addition to tungsten. FIG. 1B shows an example of a cross-sectional depiction of a vertical feature 101 to be filled with tungsten. The feature can include a feature hole 105 in a substrate 103. The hole 105 or other feature may have a dimension near the opening, e.g., an opening diameter or line width of between about 10 nm to 500 nm, for example between about 25 nm and about 300 nm. The feature hole 105 can be referred to as an unfilled feature or simply a feature. The feature 101, and any feature, may be characterized in part by an axis 118 that extends through the length of the feature, with vertically-oriented features having vertical axes and horizontally-oriented features having horizontal axes.

In some embodiments, features are trenches in a 3D NAND structure. For example, a substrate may include a wordline structure having at least 60 lines, with between 18 to 48 layers, with trenches at least 200 Å deep. Another example is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 1C shows an example of a feature 101 that has a re-entrant profile. A re-entrant profile is a profile that narrows from a bottom, closed end, or interior of the feature to the feature opening. According to various implementations, the profile may narrow gradually and/or include an overhang at the feature opening. FIG. 1C shows an example of the latter, with an under-layer 113 lining the sidewall or interior surfaces of the feature hole 105. The under-layer 113 can be for example, a diffusion barrier layer, an adhesion layer, a nucleation layer, a combination of thereof, or any other applicable material. Non-limiting examples of under-layers can include dielectric layers and conducting layers, e.g., silicon oxides, silicon nitrides, silicon carbides, metal oxides, metal nitrides, metal carbides, and metal layers. In particular implementations an under-layer can be one or more of titanium, titanium nitride, tungsten nitride, titanium aluminide, and tungsten. In some embodiments, the under-layer is tungsten-free. The under-layer 113 forms an overhang 115 such that the under-layer 113 is thicker near the opening of the feature 101 than inside the feature 101.

In some implementations, features having one or more constrictions within the feature may be filled. FIG. 1D shows examples of views of various filled features having constrictions. Each of the examples (a), (b) and (c) in FIG. 1D includes a constriction 109 at a midpoint within the feature. The constriction 109 can be, for example, between about 15 nm-20 nm wide. Constrictions can cause pinch off during deposition of tungsten in the feature, with deposited tungsten blocking further deposition past the constriction before that portion of the feature is filled, resulting in voids in the feature. Example (b) further includes a liner/barrier overhang 115 at the feature opening. Such an overhang could also be a potential pinch-off point. Example (c) includes a constriction 112 further away from the field region than the overhang 115 in example (b).

Horizontal features, such as in 3-D memory structures, can also be filled. FIG. 1E shows an example of a horizontal feature 150 that includes a constriction 151. For example, horizontal feature 150 may be a word line in a VNAND structure.

In some implementations, the constrictions can be due to the presence of pillars in a VNAND or other structure. FIG. 1F, for example, shows a plan view of pillars 125 in a VNAND or vertically integrated memory (VIM) structure 148, with FIG. 1G showing a simplified schematic of a cross-sectional depiction of the pillars 125. Arrows in FIG. 1F represent deposition material; as pillars 125 are disposed between an area 127 and a gas inlet or other deposition source, adjacent pillars can result in constrictions 151 that present challenges in void free fill of an area 127.

The structure 148 can be formed, for example, by depositing a stack of alternating interlayer dielectric layers 129 and sacrificial layers (not shown) on a substrate 100 and selectively etching the sacrificial layers. The interlayer dielectric layers may be, for example, silicon oxide and/or silicon nitride layers, with the sacrificial layers a material selectively etchable with an etchant. This may be followed by etching and deposition processes to form pillars 125, which can include channel regions of the completed memory device.

The main surface of substrate 100 can extend in the x and y directions, with pillars 125 oriented in the z-direction. In the example of FIGS. 1F and 1G, pillars 125 are arranged in an offset fashion, such that pillars 125 that are immediately adjacent in the x-direction are offset with each other in the y-direction and vice versa. According to various implementations, the pillars (and corresponding constrictions formed by adjacent pillars) may be arranged in any number of manners. Moreover, the pillars 125 may be any shape including circular, square, etc. Pillars 125 can include an annular semi-conducting material, or circular (or square) semi-conducting material. A gate dielectric may surround the semi-conducting material. The area between each interlayer dielectric layer 129 can be filled with tungsten; thus structure 148 has a plurality of stacked horizontally-oriented features that extend in the x and/or y directions to be filled.

FIG. 1H provides another example of a view of a horizontal feature, for example, of a VNAND or other structure including pillar constrictions 151. The example in FIG. 1H is open-ended, with material to be deposited able to enter horizontally from two sides as indicated by the arrows. (It should be noted that example in FIG. 1H can be seen as a 2-D rendering 3-D features of the structure, with the FIG. 1H being a cross-sectional depiction of an area to be filled and pillar constrictions shown in the figure representing constrictions that would be seen in a plan rather than cross-sectional view.) In some implementations, 3-D structures can be characterized with the area to be filled extending along two or three dimensions (e.g., in the x and y or x, y and z-directions in the example of FIG. 1G), and can present more challenges for fill than filling holes or trenches that extend along one or two dimensions. For example, controlling fill of a 3-D structure can be challenging as deposition gasses may enter a feature from multiple dimensions.

FIG. 1I depicts another example of a feature that may be filled with tungsten according to embodiments disclosed herein. In particular, FIG. 1I depicts a schematic example of a DRAM architecture including a tungsten buried wordline (bWL) 11 in a silicon substrate 9. The tungsten bWL is formed in a trench etched in the silicon substrate 9. Lining the trench is a conformal barrier layer 12 and an insulating layer 13 that is disposed between the conformal barrier layer 12 and the silicon substrate 9. In the example of FIG. 1I, the insulating layer 13 may be a gate oxide layer, formed from a high-k dielectric material such as a silicon oxide or silicon nitridematerial.

Titanium nitride (TiN) is used as a barrier in tungsten (W) wordline architectures. However, TiN/W wordline fill is limited by the resistivity scaling; because TiN has relatively high resistivity, as dimensions decrease and TiN conformal layers occupy a greater volume fraction of the trench, the resistance increases. According to various embodiments, the tungsten bWLs disclosed herein are free of TiN and other non-W barrier layers.

While TiN layers are depicted in some of the examples of features that may be filled by the methods disclosed herein, in some embodiments, tungsten may be formed directly on oxide surfaces without a barrier layer present. For example in FIG. 1H, the TiN layer may not be present. Similarly, in FIG. 1I, the tungsten bWL 11 may be formed directly on the insulating layer 13.

Examples of feature fill for horizontally-oriented and vertically-oriented features are described below. It should be noted that in most cases, the examples applicable to both horizontally-oriented or vertically-oriented features.

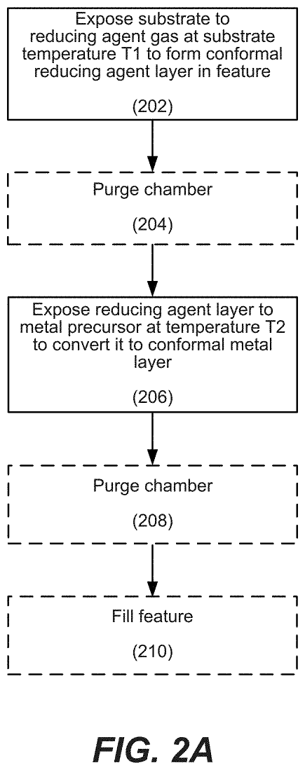

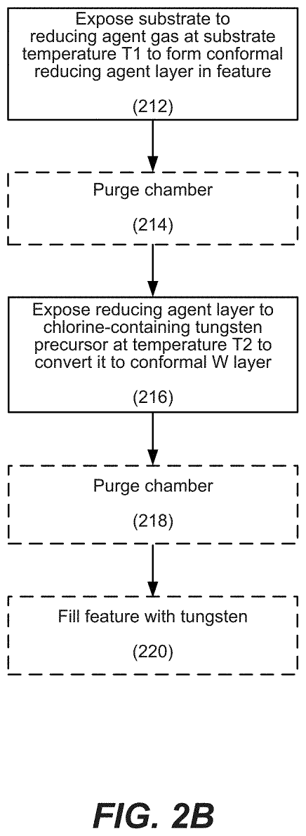

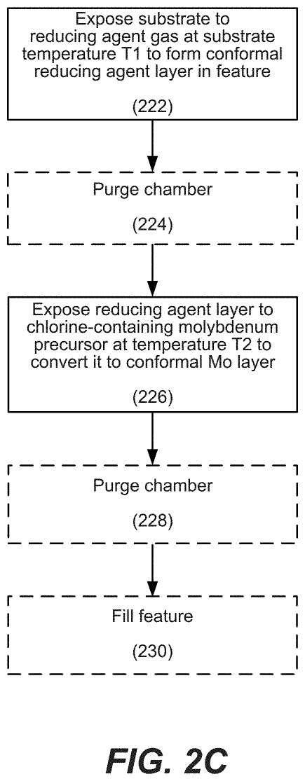

FIGS. 2A-2C provide process flow diagrams for methods performed in accordance with disclosed embodiments. In particular, FIG. 2A provides a process flow diagram for a method of depositing an elemental metal layer in a feature. FIGS. 2B and 2C provide examples of the method of FIG. 2A to deposit elemental tungsten and molybdenum, respectively.

First turning to FIG. 2A, operations 202-208 may be performed to form a conformal layer directly on at least a dielectric surface of a feature. In some embodiments, these operations are formed without prior deposition of a nucleation layer. In such operations, prior to operation 202, a substrate having no nucleation layer deposited thereon is provided.

As described below, certain operations are performed at substrate temperatures. It will be understood that substrate temperature refers to a temperature to which the pedestal holding the substrate is set. Certain disclosed embodiments may be performed at a chamber pressure between about 3 Torr and about 60 Torr. In some embodiments, chamber pressure is less than about 10 Torr. For example, in some embodiments chamber pressure is about 5 Torr.

In operation 202, the substrate is exposed to a reducing agent gas to form a reducing agent layer. In some embodiments, the reducing agent gas may be a silane, a borane, or a mixture of a silane and diborane. Examples of silanes including SiH₄ and Si₂H₆ and examples of boranes include diborane (B₂H₆), as well as BₙHₙ₊₄, BₙHₙ₊₆, BₙHₙ₊₈, BₙHₘ, where n is an integer from 1 to 10, and m is a different integer than m. Other boron-containing compounds may also be used, e.g., alkyl boranes, alkyl boron, aminoboranes (CH₃)₂NB(CH₂)₂, carboranes such as C₂BₙHₙ₊₂. In some implementations, the reducing agent layer may include silicon or silicon-containing material, phosphorous or a phosphorous-containing material, germanium or a germanium-containing material, boron or boron-containing material that is capable of reducing a tungsten precursor and combinations thereof. Further example reducing agent gases that can be used to form such layers include PH₃, SiH₂Cl₂, and GeH₄. According to various embodiments, hydrogen may or may not be run in the background. (While hydrogen can reduce tungsten precursors, it does not function as a reducing agent in a gas mixture with a sufficient amount of stronger reducing agents such as silane and diborane.)

In some embodiments, the reducing agent gas is a mixture including a small amount of a boron-containing gas, such as diborane, with another reducing agent. The addition of a small amount of a boron-containing gas can greatly affect the decomposition and sticking coefficient of the other reducing agent. It should be noted that exposing the substrate sequentially to two reducing agents, e.g., silane and diborane may be performed. However, flowing a mixture of gases can facilitate the addition of very small amounts of a minority gas, e.g., at least a 100:1 ratio of silane to diborane. In some embodiments, a carrier gas may be flowed. In some embodiments, a carrier gas, such as nitrogen (N₂), argon (Ar), helium (He), or other inert gases, may be flowed during operation 202.

In some embodiments, a reducing agent layer may include elemental silicon (Si), elemental boron (B), elemental germanium (Ge), or mixtures thereof. For example, as described below, a reducing agent layer may include Si and B. The amount of B may be tailored to achieve high deposition rate of the reducing agent layer but with low resistivity. In some embodiments, a reducing agent layer may have between 5% and 80% B for example, or between 5% and 50% B, between 5% and 30%, or between 5% and 20% B, with the balance consisting essentially of Si and in some cases, H. Hydrogen atoms be present, e.g., SiHₓ, BH_{y}, GeH_{z}, or mixtures thereof where x, y, and z may independently be between 0 and a number that is less than the stoichiometric equivalent of the corresponding reducing agent compound.

In some embodiments, the composition may be varied through the thickness of the reducing agent layer. For example, a reducing agent layer may be 20% B at the bottom of the reducing agent layer and 0% B the top of the layer. The total thickness of the reducing agent layer may be between 10 Å and 50 Å, and is some embodiments, between 15 Å and 40 Å, or 20A and 30A. The reducing agent layer conformally lines the feature.

Further details on the composition of the reducing agent gas as well as the resulting reducing agent layer are provided below.

Substrate temperature during operation 202 may be maintained at a temperature T1 for the film to be conformal. If temperature is too high, the film may not conform to the topography of the underlying structure. In some embodiments, step coverage of greater than 90% or 95% is achieved. For silane, diborane, and silane/diborane mixtures, conformality is excellent at 300° C. and may be degraded at temperatures of 400° C. or higher. Thus, in some embodiments, temperature during operation 202 is at most 350° C., or even at most 325° C., at most 315° C., or at most 300° C. In some embodiments, temperatures of less than 300° C. are used.

Operation 202 may be performed for any suitable duration. In some examples, Example durations include between about 0.25 seconds and about 30 seconds, about 0.25 seconds and about 20 seconds, about 0.25 seconds and about 5 seconds, or about 0.5 seconds and about 3 seconds.

In operation 204, the chamber is optionally purged to remove excess hydrogen that did not adsorb to the surface of the substrate. A purge may be conducted by flowing an inert gas at a fixed pressure thereby reducing the pressure of the chamber and re-pressurizing the chamber before initiating another gas exposure. Example inert gases include nitrogen (N₂), argon (Ar), helium (He), and mixtures thereof. The purge may be performed for a duration between about 0.25 seconds and about 30 seconds, about 0.25 seconds and about 20 seconds, about 0.25 seconds and about 5 seconds, or about 0.5 seconds and about 3 seconds.

In operation 206, the substrate is exposed to a metal precursor at a substrate temperature T2. Examples include tungsten-containing and molybdenum-containing precursors, though the method may also be extended to precursors of other metals. The metal precursor is a precursor that can be reduced to form an elemental metal, e.g., W or Mo.

In some embodiments, a carrier gas, such as nitrogen (N₂), argon (Ar), helium (He), or other inert gases, may be flowed during operation 206. In various embodiments, during operation 206, the amount of precursor by volume may be between about 0.1% and about 1.5%.

Operation 206 may be performed for any suitable duration. In some embodiments, it may involve a soak of the metal precursor and in some embodiments, a sequence of metal precursor pulses. According to various embodiments, operation 206 may or may not be performed in the presence of H₂. If H₂ is used, in some embodiments, it and the metal precursor may be applied in an ALD-type mode. For example:

### Pulse of H₂

Argon purge
Pulse of metal precursor with or without H₂ in background Argon purge

### Repeat

The H₂ may be used to remove byproducts off the surface, for example. However, if H₂ is used in CVD type mode (e.g., H₂ and the metal precursor are provided without pulsing), the step coverage may be compromised.

The substrate temperature T2 is high enough that the metal precursor reacts with the reducing agent layer to form a metallic layer. In some embodiments, the entire reducing agent layer may be converted to the metal. In some embodiments, most of the reducing agent layer is converted to the metal. In some embodiments, the temperature is at least 450° C., and may be at least 500° C. to obtain conversion of at or near 100%. The dependence on temperature is described in more detail below.

The resulting feature is now lined with a conformal film of the metal. It may be between 10 Å and 50 Å, and is some embodiments, between 15 Å and 40 Å, or 20 Å and 30 Å. In general, it will be about the same thickness as the reducing agent layer. In some embodiments, it may be up to 5% thicker than the reducing agent layer due to volumetric expansion during the conversion.

In operation 208, there may be an optional purge operation to purge excess metal precursor still in gas phase that did not react the reducing agent layer. A purge may be conducted by flowing an inert gas at a fixed pressure thereby reducing the pressure of the chamber and re-pressurizing the chamber before initiating another gas exposure. The chamber may be purged for any suitable duration. The chamber may be purged for a duration between about 0.25 seconds and about 30 seconds, about 0.25 seconds and about 20 seconds, about 0.25 seconds and about 5 seconds, or about 0.5 seconds and about 3 seconds. The purge gas may be any of the gases described above with respect to operation 204. In operation 210, the feature is optionally filled with metal.

FIG. 2B provides a process flow diagram for a method performed in accordance with disclosed embodiments. Operations 212-218 of FIG. 2B may be performed to form a conformal tungsten layer directly at least a dielectric surface of a feature. In some embodiments, these operations are formed without prior deposition of a tungsten nucleation layer. In such operations, prior to operation 212, a substrate having no tungsten nucleation layer deposited thereon is provided.

In operation 212, the substrate is exposed to a reducing agent gas to form a reducing agent layer. Exposure to the reducing agent gas is described above with respect to operation 202 in FIG. 2A. In some embodiments, the reducing agent layer is tuned to obtain a particular tungsten microstructure. For example, beta-tungsten has a metastable A15 cubic crystalline structure and exhibits higher resistivity than the stable body-centered cubic crystalline structure of alpha-tungsten. Boron-based reducing agent layers may lead to the presence of higher resistivity beta-tungsten in tungsten films at certain thicknesses. Silane or germane reducing agent layers may promote growth of alpha-tungsten.

In operation 214, the chamber is optionally purged to remove excess hydrogen that did not adsorb to the surface of the substrate, as described above with respect to operation 204 of FIG. 2A.

In operation 216, the substrate is exposed to a chlorine-containing tungsten precursor at a substrate temperature T2. Example chlorine-containing tungsten precursors have a chemical formula of WClₓ, where x is an integer between and including 2 and 6, such as 2, 3, 4, 5, or 6. Examples include WCl₅ and WCl₆. The chlorine-containing tungsten precursor may include a mixture of WClₓ compounds. In some embodiments, a carrier gas, such as nitrogen (N₂), argon (Ar), helium (He), or other inert gases, may be flowed during operation 216. In various embodiments, during operation 216, the amount of chlorine-containing tungsten precursor by volume may be between about 0.1% and about 1.5%. In other embodiments, a fluorine-containing precursor such as tungsten hexafluoride (WF₆) or a tungsten hexacarbonyl W(CO)₆ precursor may be used.

Operation 216 may be performed for any suitable duration. In some embodiments, it may involve a soak of WClₓ and in some embodiments, a sequence of WClₓ pulses. According to various embodiments, operation 206 may or may not be performed in the presence of H₂. If H₂ is used, in some embodiments, it and the WClₓ may be applied in an ALD-type mode. If H₂ is used, in some embodiments, it and the WClₓ may be applied in an ALD-type mode as described above with respect to FIG. 2A.

The substrate temperature T2 is high enough that the WClₓ precursor reacts with the reducing agent layer to form metallic tungsten (W). All or most of the reducing agent layer may be converted to tungsten. In some embodiments, the temperature is at least 450° C., and may be at least 500° C. to obtain conversion of at or near 100%. The dependence on temperature is described in more detail below.

The resulting feature is now lined with a conformal film of tungsten. It may be between 10 Å and 50 Å, and is some embodiments, between 15 Å and 40 Å, or 20 Å and 30 Å. In general, it will be about the same thickness as the reducing agent layer. In some 15 embodiments, it may be up to 5% thicker than the reducing agent layer due to volumetric expansion during the conversion.

In operation 218, there may be an optional purge operation to purge excess chlorine-containing tungsten precursor still in gas phase that did not react the reducing agent layer as described with respect to FIG. 2A.

In operation 220, the feature is optionally filled with tungsten. Bulk tungsten deposition may be deposited using any of the disclosed embodiments described in U.S. patent application Ser. No. 15/398,462 filed on Jan. 4, 2017, or in U.S. patent application U.S. Ser. No. 14/502,817, filed on Sep. 30, 2014, which are herein incorporated by reference for the purpose of described feature fill and bulk tungsten deposition. Bulk tungsten deposition may be performed with or without depositing a tungsten nucleation layer and may use a fluorine-containing or fluorine-free tungsten precursor.

FIG. 2C provides a process flow diagram for a method performed in accordance with disclosed embodiments. Operations 222-228 of FIG. 2C may be performed to form a conformal molybdenum layer directly at least a dielectric surface of a feature. In some embodiments, these operations are formed without prior deposition of a nucleation layer. In such operations, prior to operation 222, a substrate having no nucleation layer deposited thereon is provided.

Operations 222 and 224 may be carried out as described above with respect to operations 202 and 204 of FIG. 2A. In operation 226, the substrate is exposed to a molybdenum precursor at a substrate temperature T2. Mo-containing precursors include molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆). The molybdenum precursor may include a mixture of Mo compounds. In some embodiments, a carrier gas, such as nitrogen (N₂), argon (Ar), helium (He), or other inert gases, may be flowed during operation 226.

Operation 226 may be performed for any suitable duration and may involve a soak of the precursor or a sequence of pulses. According to various embodiments, operation 226 may or may not be performed in the presence of H₂ as described above.

The substrate temperature T2 is high enough that the molybdenum precursor reacts with the reducing agent layer to form metallic molybdenum (Mo). The entire reducing agent layer is converted to molybdenum. In some embodiments, the temperature is at least 450° C., and may be at least 500° C. to obtain conversion of at or near 100%.

The resulting feature is now lined with a conformal film of tungsten. It may be between 10 Å and 50 Å, and is some embodiments, between 15 Å and 40 Å, or 20 Å and 30 Å. In general, it will be about the same thickness as the reducing agent layer. In some embodiments, it may be up to 5% thicker than the reducing agent layer due to volumetric expansion during the conversion.

Reducing Agent Layer Formation

Results in the below table show the effect of diborane on the decomposition of silane in reducing agent layer formation on an oxide. Formation of the reducing agent layer was performed at 300° C. and 10 Torr using various mixtures of SiH₄ and B₂H₆ on blanket SiO₂. The balance of the reducing agent gas is H₂ and N₂ carrier gases in each case.

| % SiH₄ | % B₂H₆ | SiH₄ | B₂H₆ | | | | | | SiH₄ | B₂H₆ |
|---|---|---|---|---|---|---|---|---|---|---|
| in | in | Exposure | Exposure | SiH₄:B₂H₆ | Dep Rate | % Si in | % B in | | Sticking | Sticking |
| Dose | Dose | Torr-s | Torr-s | ratio | Å/cycle | layer | layer | S:B | Coef | Coef |
| 50% | 0 | 25 | 0 | ∞ | <5.0 | 100% | 0% | | 3.7E−7 | N/A |
| | | | | | discontin- | | | | | |
| | | | | | uous | | | | | |
| 45% | 0.25% | 22.5 | 0.125 | 180 | 17.1 | 76% | 24% | 3 | 2.4E−6 | 1.3E−5 |
| 25% | 1.25% | 12.5 | 0.625 | 20 | 18.0 | 40% | 60% | 0.7 | 1.7E−6 | 2.5E−5 |
| 5% | 2.25% | 2.5 | 1.125 | 2 | 9.4 | 16% | 84% | 0.2 | 1.3E−6 | 3.4E−5 |
| 0% | 2.50% | 0 | 1.250 | 0 | 6.0 | 0% | 100% | 0 | N/A | 1.1E−5 |

The above results show that a small amount of diborane greatly alters the silane decomposition. For example, the silane sticking coefficient is increased almost sevenfold by the addition of just 0.25% diborane. Co-flowing silane also increases the diborane coefficient by greater than twofold. Electron energy loss spectroscopy (EELS) analysis shows that the % B in the reducing agent layer is high relative to the % B₂H₆ in the reducing agent gas.

Conversion to Tungsten

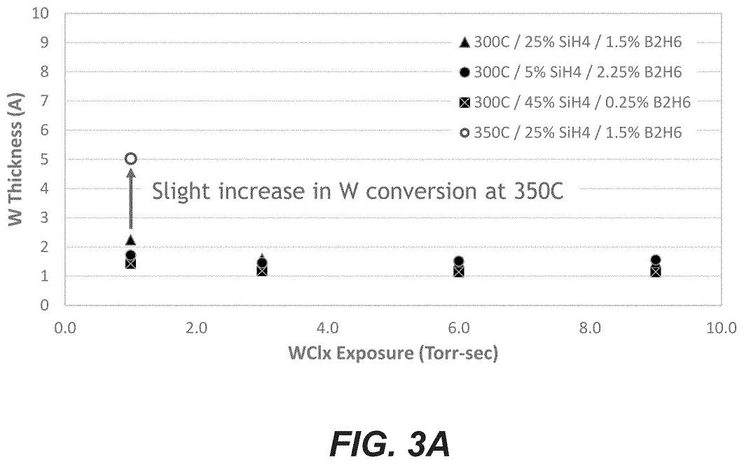

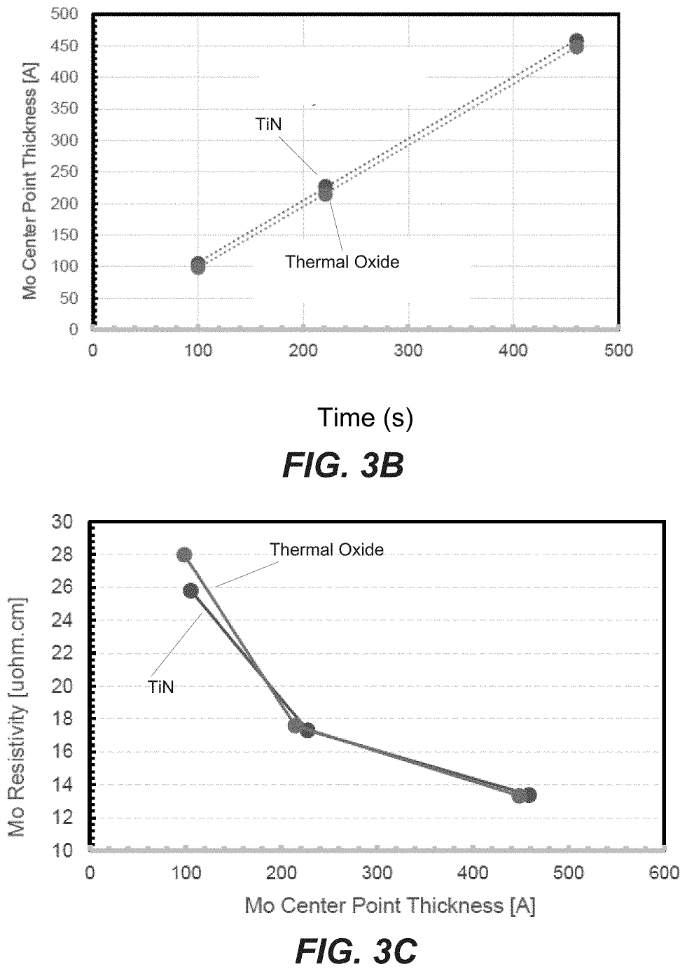

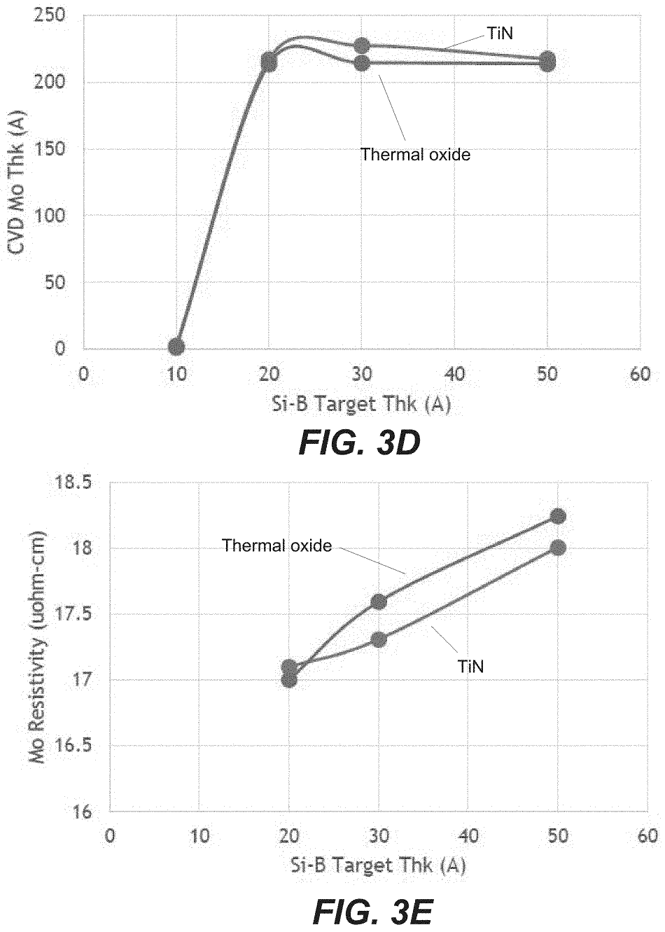

FIG. 3A shows W conversion for various reducing agent gas mixtures and WClₓ exposures at 300° C. substrate temperature during conversion. Almost none of the reducing agent layer was converted at this temperature regardless of the WClₓ exposure. A slight increase in W conversion was observed at 350° C. An increase of 10× the W exposure (as measured in Torr-s) had no impact at 350° C. Nor did testing on Al₂O₃ instead of SiO₂. This indicates that temperatures significantly higher than 350° C. may be employed, e.g., at least 500° C.

The effect of B in the reducing agent layer on tungsten conversion is shown in the below table.

| Reducing Agent Layer Formation | | | | | | | Conversion to W | | |
|---|---|---|---|---|---|---|---|---|---|
| | B₂H₆/SiH₄ | B₂H₆/SiH₄ | B₂H₆/SiH₄ | Si—B | | | H₂—W | H₂—W | W CP |
| | Soak | % SiH₄ | % B₂H₆ | thickness | Si—B | Si—B | ALD | ALD # | Thickness |
| Substrate | Temp | in Dose | in Dose | (Å, TEM) | % Si | % B | Temp | Cycles | (Å, XRF) |
| SiO₂ | 300 C. | 45% | 0.25% | 171 | 76% | 24% | 500 C. | 400× | 139 |
| | | 25% | 1.25% | 180 | 40% | 60% | | | 66 |
| | | 5% | 2.25% | 94 | 16% | 84% | | | 71 |

The results in the table above show that tungsten conversion increases with increasing concentration of Si and decreasing concentration of B in the reducing agent layer.

Results on Al₂O₃ were substantially the same as those on SiO₂.

Conversion to Molybdenum

FIG. 3B shows CVD Mo growth (thickness vs time) obtained using a Si—B reducing agent layer using a MoCl₅ precursor on both a thermal oxide (lower line) and TiN (upper line) substrate. The results show an identical growth rate on different substrates when growth is initiated on the Si—B sacrificial layer. FIG. 3C shows resistivity of the CVD Mo films; the two resistivities are comparable. The results in FIGS. 3B and 3C indicate that a Si—B reducing agent layer is an effective way to initiate growth on a variety of substrates. Similar results were obtained for MoCl₄.

FIG. 3D shows CVD Mo growth for Si—B reducing agent layers of 10 Å, 20 Å, 30 Å, and 50 Å. There is a negligible Mo deposition on the 10 Å layer, and stable thickness on 20 Å-50 Å layers. FIG. 3E shows resistivity as a function of reducing agent layer thickness, and indicates that the Mo resistivity increases slightly with increasing Si—B layer thickness. This is likely due to residual reducing agent layer left after deposition, indicating that the temperature and/or reducing agent layer composition may be adjusted to minimize or eliminate the residual layer.

Apparatus

Any suitable chamber may be used to implement the disclosed embodiments. Example deposition apparatuses include various systems, e.g., ALTUS® and ALTUS® Max, available from Lam Research Corp., of Fremont, Calif., or any of a variety of other commercially available processing systems. In some embodiments, sequential chemical vapor deposition (CVD) may be performed at a first station that is one of two, five, or even more deposition stations positioned within a single deposition chamber. Thus, for example, silane (SiH₄) and diborane (B₂H₆) may be introduced to the surface of the semiconductor substrate, at the first station, using an individual gas supply system that creates a localized atmosphere at the substrate surface to form a reducing agent layer. Another station may be used for fluorine-free tungsten conversion of the reducing agent layer. Two or more stations may be used to fill the features with bulk tungsten in parallel processing.

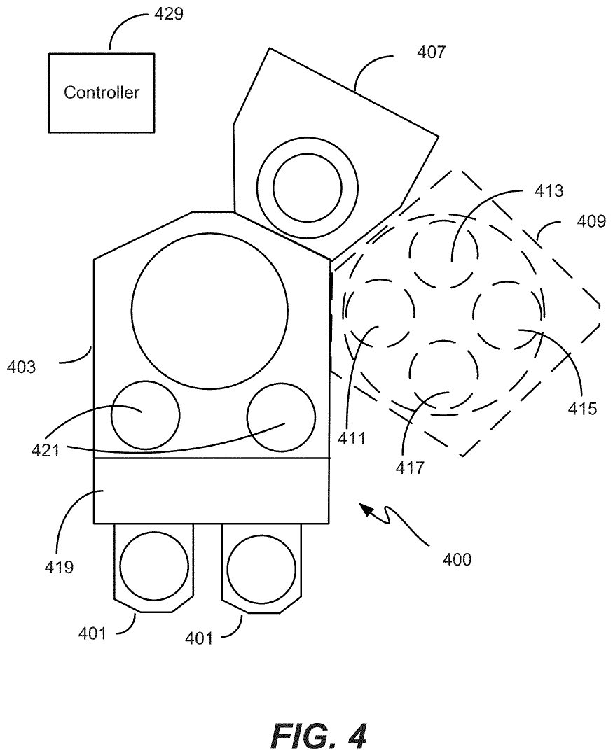

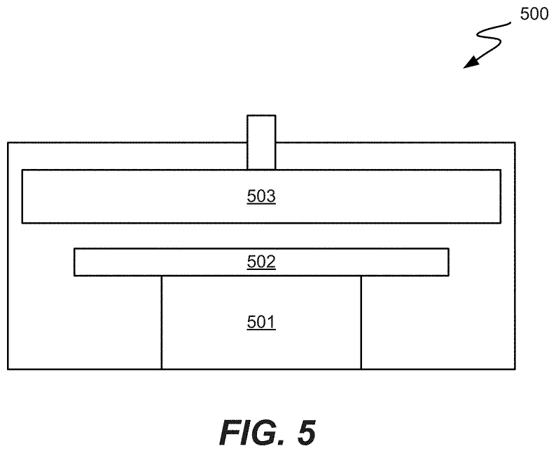

FIG. 4 is a block diagram of a processing system suitable for conducting deposition processes in accordance with embodiments. The system 400 includes a transfer module 403. The transfer module 403 provides a clean, pressurized environment to minimize risk of contamination of substrates being processed as they are moved between various reactor modules. Mounted on the transfer module 403 is a multi-station reactor 409. Multi-station reactor 409 may also be used to perform reducing agent layer deposition, fluorine-free tungsten conversion, and subsequent CVD in some embodiments. Reactor 409 may include multiple stations 411, 413, 415, and 417 that may sequentially perform operations in accordance with disclosed embodiments. For example, reactor 409 could be configured such that station 411 performs a first operation using a reducing agent, station 413 performs a second sequential operation using a WClₓ precursor, and stations 415 and 417 perform CVD. Each stations may include a heated pedestal or substrate support for independent temperature control, one or more gas inlets or showerhead or dispersion plate. An example of a deposition station 500 is depicted in FIG. 5, including substrate support 502 and showerhead 503. A heater may be provided in pedestal portion 501.

Also mounted on the transfer module 403 may be one or more single or multi-station modules 407 capable of performing plasma or chemical (non-plasma) pre-cleans. The module may also be used for various treatments to, for example, prepare a substrate for a deposition process. The system 400 also includes one or more wafer source modules 401, where wafers are stored before and after processing. An atmospheric robot (not shown) in the atmospheric transfer chamber 419 may first remove wafers from the source modules 401 to loadlocks 421. A wafer transfer device (generally a robot arm unit) in the transfer module 403 moves the wafers from loadlocks 421 to and among the modules mounted on the transfer module 403.

In various embodiments, a system controller 429 is employed to control process conditions during deposition. The controller 429 will typically include one or more memory devices and one or more processors. A processor may include a CPU or computer, analog and/or digital input/output connections, stepper motor controller boards, etc.

The controller 429 may control all of the activities of the deposition apparatus. The system controller 429 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 429 may be employed in some embodiments.

Typically there will be a user interface associated with the controller 429. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface.

Signals for monitoring the process may be provided by analog and/or digital input connections of the system controller 429. The signals for controlling the process are output on the analog and digital output connections of the deposition apparatus 400.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 429 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 429, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 429, in some implementations, may be a part of or coupled to a computer that is integrated with, coupled to the system, otherwise networked to the system, or a combination thereof. For example, the controller 429 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 429 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In the description above and in the claims, numerical ranges are inclusive of the end points of the range. For example, “between about 10 and 50 Angstroms thick” includes 10 Angstroms and 50 Angstroms. Similarly, ranges represented by a dash are inclusive of the end points of the ranges.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. It will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a substrate including a structure;
exposing the substrate to a reducing agent gas at a first substrate temperature of no more than 400° C. to form a conformal reducing agent layer on the structure;
raising the temperature of the substrate to a second substrate temperature of at least 500° C.; and
at the second substrate temperature, exposing the conformal reducing agent layer to a metal precursor to convert the conformal reducing agent layer to the metal.

2. The method of claim 1, wherein the first substrate temperature is no more than 350° C.

3. The method of claim 1, wherein the first substrate temperature is no more than 300° C.

4. The method of any of claim 1, wherein the reducing agent gas is a silicon-containing gas.

5. The method of claim 1, wherein the reducing agent gas is a boron-containing gas.

6. The method of claim 1 wherein the reducing agent gas is a mixture of a silicon-containing gas and a boron-containing gas.

7. The method of claim 6, wherein the reducing agent gas is a mixture of silane (SiH₄) and diborane (B₂H₆).

8. The method of claim 1, wherein exposing the conformal reducing agent layer to a metal precursor comprises exposing the conformal reducing agent layer to hydrogen (H₂) gas.

9. The method of claim 1, wherein the metal precursor is provided with H₂.

10. The method of claim 1, wherein exposing the conformal reducing agent layer to a metal precursor to convert the reducing agent layer to metal comprises exposing the conformal reducing agent layer to alternating pulses of H₂ and the metal precursor.

11. The method of claim 1, wherein the metal precursor is a tungsten chloride compound and the metal is tungsten.

12. The method of claim 1, wherein the metal precursor is a molybdenum-containing compound and the metal is molybdenum.

13. The method of claim 1, wherein the conformal reducing agent layer is formed directly on an oxide surface.

14. The method of claim 1, wherein the conformal reducing agent layer is formed directly on a nitride surface.

15. The method of claim 1, wherein the conformal reducing agent layer is between about 10 and 50 Angstroms thick.

16. The method of claim 6, wherein the concentration of boron in the reducing agent layer decreases with increasing thickness.

17. The method of claim 6, wherein the silicon:boron ratio in the mixture is at least 10:1.

18. A method comprising:
providing a substrate including a structure;
exposing the substrate to a mixture of a silicon-containing gas and a boron-containing gas at a first substrate temperature of no more than 400° C. to form a conformal reducing agent layer on the structure;
raising the temperature of the substrate to a second substrate temperature of at least 500° C.; and
at the second substrate temperature, exposing the conformal reducing agent layer to a tungsten-containing or molybdenum-containing precursor to convert the reducing agent layer to tungsten or molybdenum.

19. The method of claim 18, wherein the silicon:boron ratio in the mixture is at least 10:1.

20. A method comprising:
providing a substrate including a structure;
exposing the substrate to a mixture of a silicon-containing gas and a boron-containing gas to form a conformal reducing agent layer on the structure; and
exposing the conformal reducing agent layer to a molybdenum-containing precursor to convert the reducing agent layer to molybdenum.
